(19) United States
(12) Patent Application Publication
(10) Pub. No.: US 2011/0240386 A1
(43) Pub. Date: Oct. 6, 2011

(54) ELECTRIC VEHICLE WITH STRUCTURALLY INTEGRATED COMPONENTS

(75) Inventors: Kevin Robert Czinger, Brentwood, CA (US); Broc William TenHouten, Los Angeles, CA (US)

(73) Assignee: Coda Automotive, Inc., Santa Monica, CA (US)

(21) Appl. No.: 13/079,973

(22) Filed: Apr. 5, 2011

Related U.S. Application Data
(60) Provisional application No. 61/321,016, filed on Apr. 5, 2010.

(51) Int. Cl. B60L 11/18; B60K 1/04; B23P 11/00; H05K 13/00

(52) U.S. Cl. 180/65.31; 180/65.1; 29/592.1

(57) ABSTRACT

An electric vehicle (EV) includes EV components utilized as structural members within the vehicle, as a so-called stressed member. The EV component itself acts as a load-bearing structural member, thereby reducing the amount and/or mass of structural members otherwise forming the vehicle structure alone, and ultimately reducing vehicle weight.

### RELATED APPLICATIONS

This application claims priority under 35 U.S.C. §119(e) to U.S. Provisional Application Ser. No. 61/321,016, entitled “VEHICLE HAVING INTEGRATED FLOOR PAN” filed on Apr. 5, 2010, which is herein incorporated by reference in its entirety.

### FIELD

The present invention is directed to an electric vehicle, and more particularly to an electric vehicle having one or more propulsion system components and/or energy storage related components integrated into the load-bearing structure of the vehicle.

### BACKGROUND

Conventionally fueled vehicle and all-electric powered vehicles (EVs) alike include structural members which, when assembled, support the load of the vehicle, as well as the various vehicle components, as well as any dynamic loads. Typically, these components are mounted to the load-bearing structural members and the load-bearing structural members are configured to support the weight of the vehicle components.

There is a need to reduce the weight of EVs. Lowering the vehicle weight improves the efficiency of the vehicle which equates to an energy savings.

### BRIEF SUMMARY

The inventors have found that one way to reduce the weight of an EV is to utilize the EV components themselves as structural members within the vehicle, as a so-called stressed member. In this way, the EV component itself acts as a load-bearing structural member, thereby reducing the amount and/or mass of structural members otherwise forming the vehicle structure alone, and ultimately reducing vehicle weight.

According to one aspect, an electric vehicle includes a load-bearing structure and a plurality of electric vehicle components, each operatively coupled to each other and together constructed and arranged to provide a motive force. The plurality of electric vehicle components includes at least an electric motor and a battery pack. Each of the electric vehicle components includes a respective electric vehicle component housing. At least one of the electric vehicle component housings is integrated with the load-bearing structure such that said electric vehicle component housing is a stressed member within the load-bearing structure.

According to another aspect, an electric vehicle is provided. The electric vehicle includes a load-bearing structure including a first load-bearing structural member, and a plurality of electric vehicle components, each component operatively coupled to each other and together constructed and arranged to provide a motive force. The plurality of electric vehicle components includes at least an electric motor and a battery pack, each of the electric vehicle components including a respective electric vehicle component housing. At least one of the electric vehicle component housings is integrated with the first load-bearing structural member and forms a second load-bearing structural member such that said electric vehicle component housing is a stressed member within the load-bearing structure.

According to another aspect, an electric vehicle is provided. The electric vehicle includes a load-bearing structure, and at least one electric vehicle powertrain component having a housing. The housing is integrated with the load-bearing structure such that the housing is a stressed member within the load-bearing structure.

According to yet another aspect, an electric vehicle is provided. The electric vehicle includes a load-bearing structure, and a battery pack having a housing. The housing is integrated with the load-bearing structure such that the housing is a stressed member within the load-bearing structure.

According to another aspect, an electric vehicle is provided. The electric vehicle includes a load-bearing structure, and a battery pack having a housing. The battery pack housing is integrated with the load-bearing structure such that the battery pack housing is a stressed member within the load-bearing structure, and such that the battery pack housing forms a floor pan of the vehicle.

According to yet another aspect, a method of manufacturing an electric vehicle is provided. The method includes providing a load-bearing structure, and integrating an electric vehicle component housing within the load-bearing structure such that the electric vehicle component housing forms a stressed member within the load-bearing structure.

Various embodiments of the present invention provide certain advantages. Not all embodiments of the invention share the same advantages and those that do may not share them under all circumstances.

Further features and advantages of the present invention, as well as the structure of various embodiments that incorporate aspects of the invention are described in detail below with reference to the accompanying drawings.

### BRIEF DESCRIPTION OF DRAWINGS

The foregoing and other objects and advantages of the invention will be appreciated more fully from the following drawings, wherein like reference characters designate like features, in which:

FIG. 1 is a schematic perspective illustration of a portion of an electric vehicle according to one embodiment;

FIG. 2 is a schematic rear illustration of a portion of an electric vehicle according to one embodiment;

FIG. 3 is a schematic side cross-sectional illustration of a portion of an electric vehicle according to another embodiment; and

FIG. 4 is a schematic perspective view of a portion of an electric vehicle according to another embodiment.

### DETAILED DESCRIPTION OF INVENTION

The inventors recognized that integrating one or more components of the EV into the load-bearing structure of the vehicle may have certain advantages. For example, it may help to reduce the overall weight of the vehicle. Reducing the overall weight of the vehicle may be desirable because it may improve the efficiency of the vehicle. Integrating one or more components into the vehicle load-bearing structure may also be desirable because it may reduce the amount of materials associated with manufacturing the EV, which may lower production costs. Integrating one or more of the EV components into the load-bearing structure may also help to streamline the manufacturing process. Further, integrating one or more of the EV components into the load-bearing structure may increase the structural stiffness and/or rigidity of the load-bearing structure.

Many of the components traditionally located in an EV include a separate housing which may be configured to provide physical protection and/or electromagnetic interference (EMI) insulation. For example, one component of the EV may include a housing to seal it from contaminants, and/or to otherwise make the component more robust to withstand the automotive environment. Because these components may already require a robust housing, integrating these components, such as the component housing, into the vehicle's load-bearing structure may enhance the product design, providing a robust vehicle structure.

The embodiments described herein may be used with any type of EV. For example, it is contemplated that that vehicle is powered exclusively by electricity. It is also contemplated that the vehicle is a hybrid electric vehicle, and may, for example be a plug-in hybrid electric vehicle. The vehicle may be powered by a combination of batteries, fuel cells, and/or gasoline.

In a conventional electric vehicle, each EV component generally has one primary purpose. For example, the motor is typically used to provide motive force. When one of these components is integrated with the load-bearing structure of the vehicle, the component now serves a second purpose, as a portion of the load-bearing structure and acting as a stressed member within the load-bearing structure. In this regard, the EV component housing itself may be a structural member of the vehicle's load-bearing structure or otherwise integrated with another structural member of the vehicle's load-bearing structure. In either case, the component housing becomes a stressed member within the vehicle's load-bearing structure. In other embodiments, the EV component may not include a housing and the component itself becomes a stressed member within the vehicle's load-bearing structure.

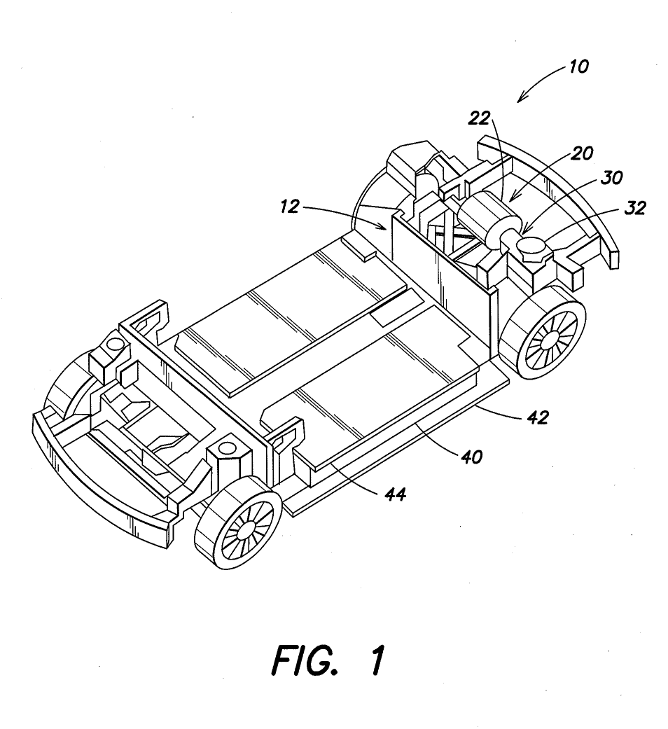

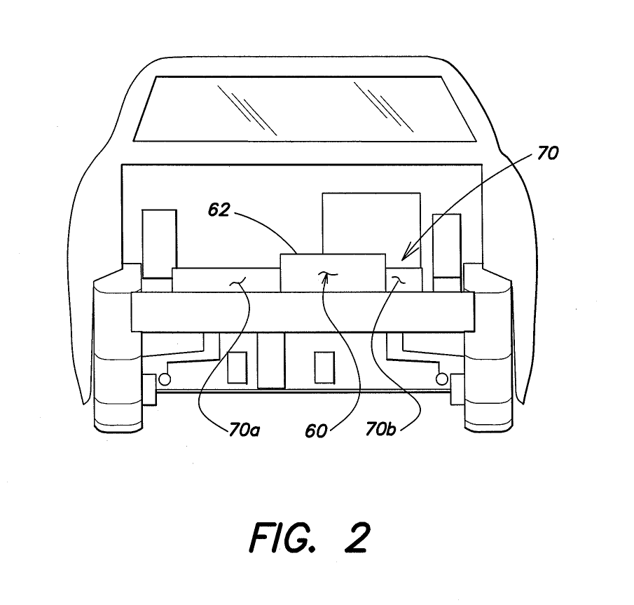

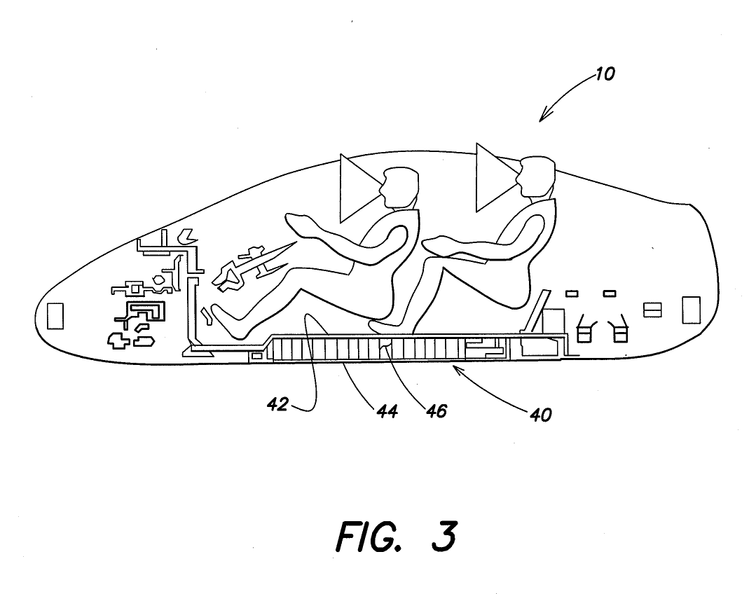

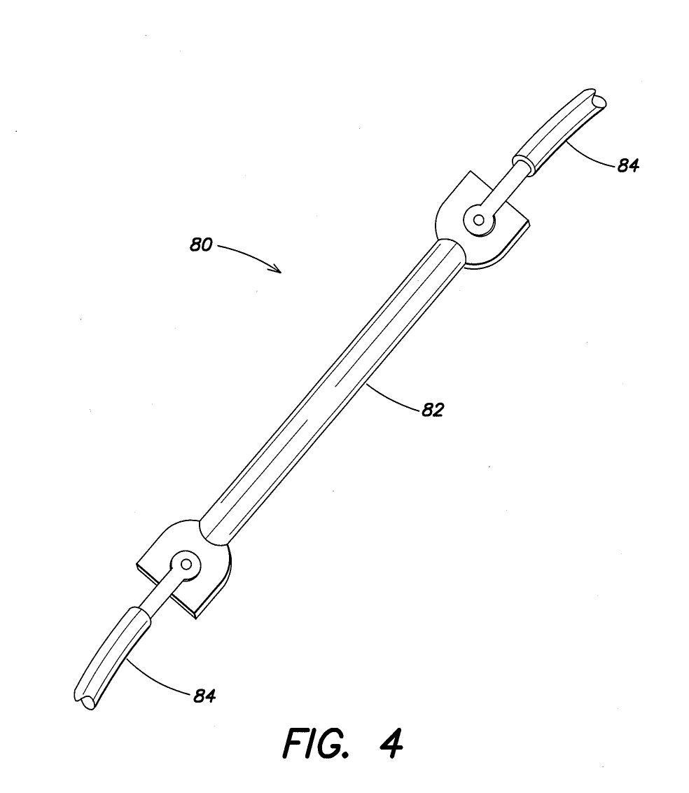

Turning now to the figures, FIG. 1 is a schematic illustration of a portion of an exemplary EV 10. The vehicle 10 has a load-bearing structure 12 (only a portion of which is shown in FIG. 1) and a plurality of EV components which are operatively coupled to each other to provide a motive force. For example, the vehicle 10 may include an electric motor 20, a power inverter, represented as reference numeral 60 (see FIG. 2), and a battery pack 40 (see also FIG. 3). Other components include a generator, a charger and a dc/dc converter, and as such, may also be represented as reference numeral 60 in FIG. 2. In still other embodiments, the EV component may be a power and/or electrical signal transmission conductor 80, as shown in FIG. 4. The electric motor 20 is configured to convert electrical energy into mechanical motion, the power inverter is configured to supply power to the motor 20, and the battery pack 40 is configured to provide stored energy to power the motor vehicle. The EV may also include a transaxle 30 which may be configured to be a combination of a transmission gearbox and final drive. As discussed in greater detail below, unlike a traditional EV, where each of these components are mounted to the vehicle's load-bearing structure, according to an aspect of the invention, one or more of these components are integrated with the load-bearing structure 12 to form a stressed member within the load-bearing structure. In particular, one or more of these EV components may include a housing, and the housing may be integrated with a first structural member of the load-bearing structure such that the housing forms a second structural member of the load-bearing structure.

It should be recognized that there are a variety of ways in which the one or more components of the EV may be integrated into the load-bearing structure to become a stressed member. For example, in one embodiment, the component housing is integrally formed with a structural member of the load-bearing structure. It is contemplated that the component housing may be cast, stamped, machined, molded or co-molded with the structural member of the vehicle structure 12, or otherwise integrally formed with the vehicle structure such that the component housing and the structural member are formed of a unitary piece. The component housing may be joined to the structural member employing any one or more suitable arrangement, as the present invention is not limited in this respect, such as for example, welding, adhesively bonding, and mechanically fastening, such as riveting or bolting, or combinations thereof. Thus, in one embodiment, the component housing may be integrated with the vehicle structure 12 by the housing being welded to the structural member. In this respect, the component housing and the structural member may initially be made separately but may be welded together to form a unitary piece. In one embodiment, the component housing may be integrated with the structural member by the component housing being bolted to the structural member with one or more bolts.

As illustrated in FIGS. 1 and 3, in one embodiment, the battery pack 40 has a housing 44 which forms the vehicle floor pan 42, and thus becomes a structural component of the vehicle's load-bearing structure. The vehicle floor pan 42 is a portion of the vehicle forming the floor of the vehicle, and may for example be a large piece of stamped metal. In the embodiment shown in FIGS. 1 and 3, the battery pack 40 is integrated with the vehicle floor pan 42. In other words, the component housing, in essence, becomes the floor pan 42. It should be appreciated that in another embodiment, the battery pack housing 44 (or another component housing) may be integrated with the floor pan (or integrated with another structural member) without also forming (i.e. replacing) the floor pan 42.

The battery pack housing 44 may be configured to protect the battery cells 46. For example, the housing 44 may be made of a substantially nonporous material to prevent unwanted contaminants from contacting the battery cells 46. The housing 44 may also be made of a substantially rigid material to protect the battery cells 46. As mentioned above, it is contemplated that the battery pack housing 44 is integrally formed with a portion of the load-bearing structure of the vehicle, such as the floor pan 42. It is also contemplated that the battery pack housing 44 is welded to, bolted to, or otherwise integrated with a portion of the load-bearing structure.

In one embodiment, at least one of the EV powertrain components is integrated with the load-bearing structure of the vehicle. It should be recognized that the EV powertrain components are the components which are configured to generate and transmit power to the vehicle. The powertrain components may be configured to transform stored energy into kinetic energy to move the vehicle. The EV powertrain components include, but are not limited to the electric motor 20, the power inverter, the charger, and the dc/dc converter. The powertrain component may include a housing which may be integrated with a structural member of the load-bearing structure such that the powertrain component housing is a stressed member.

For example, as shown in FIG. 2, in one embodiment, the housing 62 of the power inverter and/or the dc/dc converter and/or the charger is integrated with one or more structural members of the load-bearing structure. In this particular embodiment, the housing 62 is integrated with a cross member 70, which is positioned in a rear portion of the car and extends substantially along the rear axle between the left and right wheels. In one embodiment, the cross member 70 includes a first structural member 70a and a second structural member 70b such that the cross-member 70 is essentially discontinuous at the housing 62 and each structural member 70a, 70b may be integrated with the housing 62 such as, for example, by joining. It is also contemplated that the cross member 70 may be integrated with the housing 62 by the housing 62 being integrally formed with the cross member 70.

Furthermore, it is also contemplated that a continuous cross member 70 may be employed that is reinforced by the housing 62. The continuous cross member 70 may extend through the housing 62 and the cross member 70 may be integrated with the housing 62, for example, by welding or bolting or other joining techniques, such that the housing 62 reinforces the cross member 70. That is, the housing 62 and the structural member, in this example, the cross member 70, may be integrated by being designed and formed as a single structure.

As shown in FIG. 1, the motor 20 includes a motor housing 22 which is integrated with the load-bearing structure to become a stressed member within the load-bearing structure. In one embodiment, the motor housing 22 is integrated with a structural member adjacent an axle. It should be appreciated that the vehicle may be a front-wheel drive vehicle, a rear-wheel drive vehicle or a four wheel or all wheel drive vehicle, as the present invention is not limited in this regard. In one embodiment, the motor is integrated with a structural member adjacent the rear axle of the vehicle. In another embodiment, the motor is integrated with a structural member adjacent the front axle of the vehicle. For vehicles where the motor is located at a mid area, in one embodiment, the motor may be integrated with a structural member located at the mid section of the vehicle.

As also shown in the embodiment of FIG. 1, the transaxle 30 includes a transaxle housing 32 which may be integrated with a structural member of the load-bearing structure to thereby become a stressed member within the load-bearing structure. In one embodiment, the transaxle housing 32 is also integrated with a rear portion of the load-bearing structure adjacent the rear axle.

It should be appreciated that in another embodiment, the various component housings may be integrated with the load-bearing structure in other locations and configurations. Although some of the above-described components are integrated with a rear structural member, it is also contemplated that one or more component housings may be integrated with a structural member located at a central portion of the vehicle, such as, but not limited to, the floor pan 42. It is also contemplated that one or more component housings may be integrated with a front structural member, and may, for example be integrated with a structural member of the load-bearing structure adjacent the front axle.

As shown in FIG. 4, a power and/or signal transmission conductor 80 may be integrated into the load-bearing structure. In the embodiment shown, the conductor is integrated into a structural member 82. In this embodiment, the structural member may be formed of a conductive material such that it can not only support the loads of the vehicle for which it is designed, but also transmit power and/or electrical signals. On one embodiment, one end of the structural element 82 is connected to a first cable 84 via a suitable connector and the other end of the other end is connected to a second cable 84 via a suitable connector, allowing power and/or signals to be transmitted from one cable 82 to the other 84. Though not shown, the cable, connectors, and structural member may be suitably electrically insulated.

The load-bearing structure of the vehicle must be made of a material that is capable of supporting the weight of all of the vehicle components, the weight of the passengers and the passengers' possessions, and driving and impact loads. In one embodiment, one or more structural members is made of a carbon laminate. It is also contemplated that one or more structural components is made of at least one of the following materials: aluminum, magnesium, fiber reinforced plastic (FRP), thermo plastic, steel, honeycomb structures (such as honeycomb aluminum), pre-impregnated fiber reinforced plastic, super plastic formed aluminum, and cast aluminum.

Traditionally, the EV component housings are made of a material that is able to protect and/or insulate the internal components. However, when at least one of the EV component housings is structural member of the load-bearing structure or otherwise integrated with another structural member (in either case forming a stressed member within the vehicle's load-bearing structure), the EV component housings must also be made of material that is capable of supporting the load. Accordingly, in one embodiment, the EV component housing is made of the same material as the structural member with which it is integrated. In one embodiment, the EV component housing is made of a carbon laminate. It is also contemplated that the EV component housing is made of at least one of the following materials: aluminum, magnesium, fiber reinforced plastic (FRP), thermo plastic, steel, honeycomb structures (such as honeycomb aluminum), pre-impregnated fiber reinforced plastic, super plastic formed aluminum, and cast aluminum.

It should be appreciated that various embodiments of the present invention may be formed with one or more of the above-described features. The above aspects and features of the invention may be employed in any suitable combination as the present invention is not limited in this respect. It should also be appreciated that the drawings illustrate various components and features which may be incorporated into various embodiments of the present invention. For simplification, some of the drawings may illustrate more than one optional feature or component. However, the present invention is not limited to the specific embodiments disclosed in the drawings. It should be recognized that the present invention encompasses embodiments which may include only a portion of the components illustrated in any one drawing figure, and/or may also encompass embodiments combining components illustrated in multiple different drawing figures.

It should be understood that the foregoing description of various embodiments of the invention are intended merely to be illustrative thereof and that other embodiments, modifications, and equivalents of the invention are within the scope of the invention recited in the claims appended hereto.

What is claimed is:

1. An electric vehicle comprising:
load-bearing structure; and
a plurality of electric vehicle components, each operatively coupled to each other and together constructed and arranged to provide a motive force, the plurality of electric vehicle components including at least an electric motor and a battery pack, each of the electric vehicle components including a respective electric vehicle component housing;
wherein at least one of the electric vehicle component housings is integrated with the load-bearing structure such that said electric vehicle component housing is a stressed member within the load-bearing structure.

2. The electric vehicle of claim 1, wherein the load-bearing structure comprises a plurality of structural members and wherein at least a portion of the electric vehicle component housing is integrally formed with one of the structural members.

3. The electric vehicle of claim 1, wherein the load-bearing structure comprises a plurality of structural members and wherein at least a portion of the electric vehicle component housing is integrally joined with one of the structural members.

4. The electric vehicle of claim 1, wherein the electric vehicle component housing is joined to the first structural member employing at least one of a plurality of joining arrangements including welding, adhesively bonding, and mechanically fastening.

5. The electric vehicle of claim 1, wherein the plurality of electric vehicle components further includes at least one of a power inverter, a generator, a conductor, a charger and a dc/dc converter.

6. An electric vehicle comprising:
a load-bearing structure including a first load-bearing structural member; and
a plurality of electric vehicle components, each operatively coupled to each other and together constructed and arranged to provide a motive force, the plurality of electric vehicle components including at least an electric motor, and a battery pack, each of the electric vehicle components including a respective electric vehicle component housing;
wherein at least one of the electric vehicle component housings is integrated with the first load-bearing structural member and forms a second load-bearing structural member such that said electric vehicle component housing is a stressed member within the load-bearing structure.

7. The electric vehicle of claim 6, wherein at least a portion of the electric vehicle component housing is integrally formed with the first structural member.

8. The electric vehicle of claim 6, wherein the electric vehicle component housing is joined to the first structural member employing at least one of a plurality of joining arrangements including welding, adhesively bonding, and mechanically fastening.

9. The electric vehicle of claim 6, wherein the battery pack housing forms a floor pan of the vehicle.

10. The electric vehicle of claim 6, wherein the plurality of electric vehicle components further includes at least one of a power inverter, a generator, a conductor, a charger and a dc/dc converter.

11. An electric vehicle comprising:
a load-bearing structure; and
at least one electric vehicle powertrain component having a housing, the housing integrated with the load-bearing structure such that the housing is a stressed member within the load-bearing structure.

12. The electric vehicle of claim 11, wherein the at least one electric vehicle powertrain component at least one of an electric motor, power inverter, a generator, a conductor, a charger and a dc/dc converter.

13. The electric vehicle of claim 11, wherein at least a portion of the electric vehicle component housing is integrally formed with the load-bearing structure.

14. The electric vehicle of claim 11, wherein the load-bearing structure comprises a plurality of load-bearing structural members.

15. The electric vehicle of claim 14, wherein the electric vehicle component housing is joined to a structural member employing at least one of a plurality of joining arrangements including welding, adhesively bonding, and mechanically fastening.

16. An electric vehicle comprising:
a load-bearing structure; and
a battery pack having a housing, the housing integrated with the load-bearing structure such that the housing is a stressed member within the load-bearing structure.

17. The electric vehicle of claim 16, wherein at least a portion of the battery pack housing is integrally formed with the load-bearing structure.

18. The electric vehicle of claim 16, wherein the load-bearing structure comprises a plurality of load-bearing structural members.

19. The electric vehicle of claim 18, wherein the battery pack housing is joined to a structural member employing at least one of a plurality of joining arrangements including welding, adhesively bonding, and mechanically fastening.

20. The electric vehicle of claim 16, wherein the battery pack housing forms a floor pan of the vehicle.

21. A method of manufacturing an electric vehicle comprising:
providing a structural member of a load-bearing structure; and
integrating an electric vehicle component housing with the structural member such that the electric vehicle component housing forms a stressed member within the load-bearing structure.

22. The method of claim 21, wherein the electric vehicle component housing is at least one of a battery pack housing, an electric motor housing, power inverter housing, a generator housing, a conductor, a charger housing and a dc/dc converter housing.

23. The method of claim 22, wherein the integrating act includes integrally forming at least a portion of the electric vehicle component housing with the structural member of the load-bearing structure.

24. The method of claim 23, wherein the integrating act includes joining to a structural member employing at least one of a plurality of joining arrangements including welding, adhesively bonding, and mechanically fastening.
